(19) United States
(12) Patent Application Publication
(10) Pub. No.: US 2011/0187392 A1
(43) Pub. Date: Aug. 4, 2011

(54) FLOW METER

(76) Inventors: Jed Babbington Stevens, Mission Viejo, CA (US); Gregory Scott Sprenger, Evergreen, CO (US); Michael J. Gish, Colorado Springs, CO (US)

(21) Appl. No.: 13/021,210

(22) Filed: Feb. 4, 2011

Related U.S. Application Data
(60) Provisional application No. 61/301,445, filed on Feb. 4, 2010.

(51) Int. Cl. G01R 27/08

(52) U.S. Cl. 324/691

(57) ABSTRACT

A flow meter includes a main body having a first end and a second end, a flexible electrical resistor coupled to the main body and extending outwardly from the second end thereof, wherein an electrical resistance of the flexible electrical resistor varies in response to a flexure thereof, and an electrical circuit in electrical communication with the electrical resistor to detect a flexure of the electrical resistor.

### CROSS REFERENCE TO RELATED APPLICATIONS

This application is entitled to the benefit of, and claims priority to, U.S. provisional patent application Ser. No. 61/301,445 filed Feb. 4, 2010, the entire disclosure of which is incorporated herein by reference.

### FIELD OF THE INVENTION

The present invention relates to flow meters and more particularly to a meter for use in connection with the measurement of fluid flow in a piping system.

### DESCRIPTION OF THE PRIOR ART

Flow measurement in pipes is essential to many fluid processes. In many cases, flow measurement is needed after a piping system has been completed, and no flowmeter has been installed into the original pipework. Accordingly, flow measurement can be very difficult to obtain in existing pipework. Retrofitting of flowmeters is usually expensive. Typically, an ultrasonic flowmeter, which can measure the flow through the pipe walls, is secured to an exterior of the pipework. However, conventional ultrasonic flowmeters are expensive.

In most cases, the piping system contains small fittings formed along the piping in various locations. The fittings are typically used for filter differential pressure measurement and sampling of the fluid, for example. In many cases, the fittings are ¼″ female pipe thread couplings.

To measure a flowrate easily and inexpensively is desirable for a variety of reasons. In some cases, parallel piping is present, and the flowrate in each leg of the piping is desired. Parallel piping may be present to accommodate multiple filter vessels, such as in airport fuel delivery systems. For proper assessment of each filter, the flowrate through each individual filter is needed to provide data to properly correct the differential pressure of each filter in the bank of filters.

The aviation fuel industry is in need of an automatic device for use in a fuel system to generate corrected differential pressures for the fluid flow of associated fuel filters.

### SUMMARY OF THE INVENTION

Concordant and consistent with the present invention, a flow meter has been developed which may be economically produced and thence capable of being readily inserted in an existing piping systems used in the aviation fuel industry, for example.

In one embodiment, a flow meter comprises: a main body having a first end and a second end; a flexible electrical resistor coupled to the main body and extending outwardly from the second end thereof, wherein an electrical resistance of the flexible electrical resistor varies in response to a flexure thereof; and an electrical circuit in electrical communication with the electrical resistor to detect a flexure of the electrical resistor.

In another embodiment, an insertable deflection flow meter for a pipe, the flow meter comprises: a main body having a first end and a second end, the main body releasably coupled to the pipe; a flexible electrical resistor coupled to the main body and extending outwardly from the second end thereof, wherein an electrical resistance of the flexible electrical resistor is varied in response to a flexure thereof; and an electrical circuit in electrical communication with the electrical resistor to measure the electrical resistance of the flexible electrical resistor.

The present invention also includes methods a method of measuring a flow velocity of a transient fluid.

One method comprises the steps of: coupling a flow meter to a pipe, the flow meter including: a main body having a first end and a second end, the second end disposed in an interior of the pipe; and a flexible electrical resistor coupled to the main body and extending outwardly from the second end thereof, wherein an electrical resistance of the flexible electrical resistor is varied in response to a flexure thereof; passing a fluid through the pipe, the fluid causing the flexible electrical resistor to flex from a resting configuration; and sensing the flexure of the flexible electrical resistor.

### BRIEF DESCRIPTION OF THE DRAWINGS

The above, as well as other advantages of the present invention, will become readily apparent to those skilled in the art from the following detailed description of the preferred embodiment when considered in the light of the accompanying drawings in which:

FIG. 1 is a side elevational view of a flowmeter embodying the concepts of the present invention for incorporation in an existing pipe of a fluid processing system;

FIG. 2 is a front elevational view of the flowmeter illustrated in FIG. 1 coupled to a wall of a pipe, with the pipe shown in section;

FIG. 3 is an enlarged fragmentary side elevational view taken from circle 3 of FIG. 1;

FIG. 4 is a fragmentary side elevational view of the flowmeter of FIGS. 1-3 illustrating a deflection of a flexible electrical resistor caused by a force of a transient fluid in an associated pipe, with the pipe shown in section; and

FIG. 5 is an enlarged fragmentary side elevational view taken from circle 5 of FIG. 4.

### DETAILED DESCRIPTION OF THE PREFERRED EMBODIMENT OF THE INVENTION

The following detailed description and appended drawings describe and illustrate various embodiments of the invention. The description and drawings serve to enable one skilled in the art to make and use the invention, and are not intended to limit the scope of the invention in any manner. In respect of the methods disclosed, the steps presented are exemplary in nature, and thus, the order of the steps is not necessary or critical.

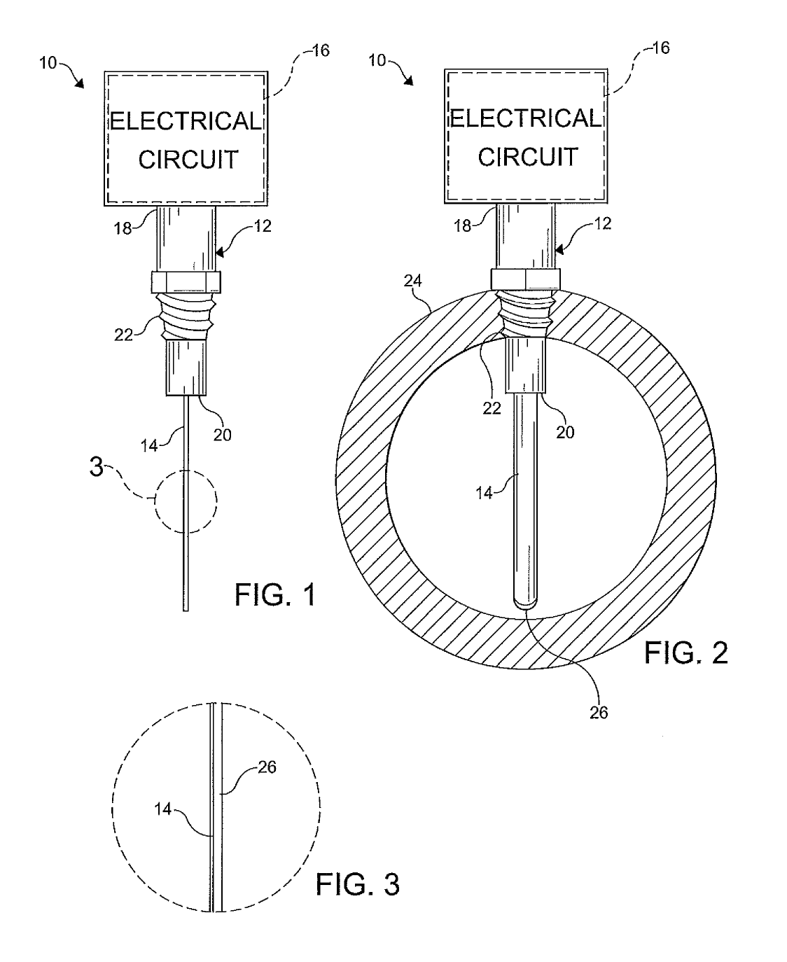

FIGS. 1-5 illustrate a flow meter 10 according to an embodiment of the present invention. As shown, the flow meter 10 includes a main body 12 (i.e. housing), a flexible electrical resistor 14, and an electrical circuit 16 in electrical communication with the flexible electrical resistor 14. It is understood that the flow meter 10 can include additional components. The flow meter 10 is typically disposed within a fluid processing system (not shown). It is understood that the flow meter 10 can be coupled to or integrated with any system or fluid conduit.

The main body 12 includes a first end 18 and a second end 20. As a non-limiting example, the main body 12 can include a threaded portion 22 (e.g. 0.25 inch National Pipe Thread Tapered Thread (NPT)) configured to engage an opening or female threaded region of a pipe 24. As a further non-limiting example, the main body 12 can be disposed through an opening in a wall of a pipe 24 or a fluid conduit having a hollow interior for conducting a flow of a fluid therethrough. Typically, the second end 20 of the main body 12 is disposed within a hollow interior of the pipe 24 and the first end 18 is disposed adjacent an exterior of the pipe 24, as shown in FIG. 2.

The flexible electrical resistor 14 is coupled to the main body 12 and configured to extend outwardly from the second end 20 of the main body 12. The flexible electrical resistor 14 is a variable resister having a resistance that varies based upon a deflection thereof. As a non-limiting example, the flexible electrical resistor 14 can be a plastic covered resistive component or a resistant ink deposited on a plastic substrate. As a further non-limiting example, the flexible electrical resistor 14 can be similar to the variable resistors illustrated and described in U.S. Pat. Nos. 5,157,372 and 5,309,135, hereby incorporated herein by reference in their entirety.

In certain embodiments, the flexible electrical resistor 14 includes a structural backing 26 or backing spring coupled thereto. The structural backing 26 extends along at least a portion of a length of the flexible electrical resistor 14. The structural backing 26 can be formed from any material having an elastic quality such as a plastic for example. As a further non-limiting example, the mechanical characteristics of a material used to form the structural backing 26 are tailored to a specific expected flow velocity of a fluid passing by the flexible electrical resistor 14.

The electrical circuit 16 is in electrical communication with the flexible electrical resistor 14 and is typically disposed at the first end 18 of the main body 12. The electrical circuit 16 includes circuit parameters (e.g. components and configurations) capable of converting a flexure of the flexible electrical resistor 14 to electrical units including at least one of a current, a frequency, and a voltage. One skilled in the art would understand that an electrical signal can be applied to the flexible electrical resistor 14, wherein a change in the electrical resistance of the flexible electrical resistor 14 due to a flexure of the same would create a measurable change in the electrical signal applied to the flexible electrical resistor 14. Accordingly, the electrical signal applied to the flexible electrical resistor 14 can be monitored to determine a flexure of the flexible electrical resistor 14. However, other circuit parameters and methods of determining flexure of the flexible electrical resistor 14 can be used, as appreciated by one skilled in the art.

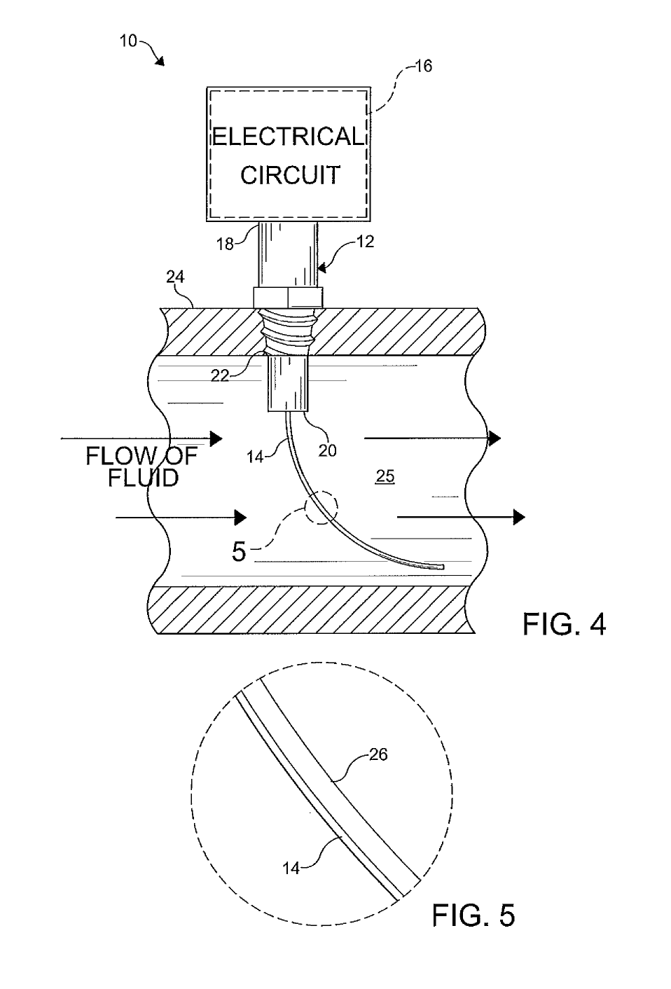

In use, the flow meter 10 including the arrangement of the flexible electrical resistor 14 with the structural backing 26 is mounted into a coupling of the pipe 24. The flexible electrical resistor 14 and the structural backing 26 define a “protruding finger”, which extends into an interior of the pipe 24. As shown in FIGS. 4-5, a flow of fluid through the pipe 24 causes the arrangement of the flexible electrical resistor 14 with the structural backing 26 to deflect. The electrical circuit 16 provides an output as a function of a flow velocity of the flow of fluid for conversion/transfer of the output to appropriate readouts for user interaction. The flow velocity of the fluid can be converted to a flowrate using an inside diameter of the pipe 24 at turbulent flow levels, as appreciated by one skilled in the art. It is understood that the arrangement of the flexible electrical resistor 14 with the structural backing 26 will return to a “zero” or normal at rest configuration (i.e. resting configuration) level when the flow of fluid is not present.

From the foregoing description, one ordinarily skilled in the art can easily ascertain the essential characteristics of this invention and, without departing from the spirit and scope thereof, can make various changes and modifications to the invention to adapt it to various usages and conditions.

What is claimed is:

1. A flow meter comprising:
a main body having a first end and a second end;
a flexible electrical resistor coupled to the main body and extending outwardly from the second end thereof, wherein an electrical resistance of the flexible electrical resistor varies in response to a flexure thereof; and
an electrical circuit in electrical communication with the electrical resistor to detect a flexure of the electrical resistor.

2. The flow meter according to claim 1, wherein the main body includes a threaded section.

3. The flow meter according to claim 2, wherein the threaded section is a tapered threaded section.

4. The flow meter according to claim 1, wherein the flexible electrical resistor includes a structural backing formed from an elastic material.

5. The flow meter according to claim 1, wherein the electrical circuit is disposed adjacent the first end of the main body.

6. The flow meter according to claim 1, wherein the electrical circuit includes circuit parameters capable of converting the flexure of the flexible electrical resistor to electrical units including at least one of a current, a frequency, and a voltage.

7. An insertable deflection flow meter for a pipe, the flow meter comprising:
a main body having a first end and a second end, the main body releasably coupled to the pipe;
a flexible electrical resistor coupled to the main body and extending outwardly from the second end thereof, wherein an electrical resistance of the flexible electrical resistor is varied in response to a flexure thereof; and
an electrical circuit in electrical communication with the electrical resistor to measure the electrical resistance of the flexible electrical resistor.

8. The flow meter according to claim 7, wherein the main body includes a threaded section coupled to the pipe.

9. The flow meter according to claim 8, wherein the threaded section is a tapered threaded section.

10. The flow meter according to claim 7, wherein the second end of the main body is disposed in an interior of the pipe.

11. The flow meter according to claim 7, wherein the first end is disposed adjacent an exterior surface of the pipe.

12. The flow meter according to claim 7, wherein the flexible electrical resistor includes a structural backing formed from an elastic material.

13. The flow meter according to claim 7, wherein the electrical circuit is disposed adjacent the first end of the main body.

14. The flow meter according to claim 7, wherein the electrical circuit includes circuit parameters capable of converting the flexure of the flexible electrical resistor to electrical units including at least one of a current, a frequency and a voltage.

15. The flow meter according to claim 7, wherein the electrical circuit includes circuit parameters capable of converting the electrical resistance of the flexible electrical resistor to a flow velocity of a transient fluid passing through the pipe.

16. A method of measuring a flow velocity of a transient fluid, the method comprising the steps of:
coupling a flow meter to a pipe, the flow meter including: a main body having a first end and a second end, the second end disposed in an interior of the pipe; and a flexible electrical resistor coupled to the main body and extending outwardly from the second end thereof, wherein an electrical resistance of the flexible electrical resistor is varied in response to a flexure thereof;
passing a fluid through the pipe, the fluid causing the flexible electrical resistor to flex from a resting configuration; and
sensing the flexure of the flexible electrical resistor.

17. The method according to claim 16, wherein the main body includes a threaded section.

18. The method according to claim 16, wherein the flexible electrical resistor includes a structural backing formed from an elastic material.

19. The method according to claim 16, wherein the step of sensing the flexure of the flexible electrical resistor is accomplished by an electrical circuit in electrical communication with the flexible electrical resistor.

20. The method according to claim 19, wherein the electrical circuit includes circuit parameters capable of converting the flexure of the flexible electrical resistor to electrical units including at least one of a current, a frequency, and a voltage.
